(19) United States
(12) Patent Application Publication
(10) Pub. No.: US 2012/0266053 A1
(43) Pub. Date: Oct. 18, 2012

(54) SECURITY COMMUNICATION METHOD BETWEEN DEVICES

(75) Inventors: Se Jin KANG, Soeul (KR); Kwan Ok KIM, Seoul (KR)

(73) Assignee: UPINES Co. Ltd., Seoul (KR)

(21) Appl. No.: 13/098,463

(22) Filed: May 1, 2011

(30) Foreign Application Priority Data
Apr. 18, 2011 (KR) 10-2011-0035608

(51) Int. Cl. H03M 13/09; G06F 11/10

(52) U.S. Cl. 714/807; 714/E11.032

(57) ABSTRACT

There is provided a security communication method between devices to tighten the security of data by changing CRC polynomials and scramble codes in the communication between the devices.

The security communication method between devices, which is a communication method between a master device and one or more slave devices, comprises the steps of: a) storing two or more CRC polynomials and two or more scramble codes in each of the master device and the one or more slave devices; b) allocating the two or more CRC polynomials and the two or more scramble codes to each of the one or more slave devices by the master device; and c) performing each data transmission between the master device and the one or more slave device, based on the CRC polynomials and scramble codes allocated in the step b).

### CROSS-REFERENCE TO RELATED APPLICATION

This application claims the benefit of Korean Patent Application No. 2011-0035608, filed Apr. 18, 2011, the disclosure of which is hereby incorporated herein by reference in its entirety.

### BACKGROUND OF THE INVENTION

1. Field of the Invention

The present invention relates to a security communication method for tightening the security of data transmitted upon the communication between a parent host processor and a child device and, more particularly, to a security communication method between devices for tightening the security of data by changing CRC polynomials and scramble codes in the communication between the devices.

2. Description of the Related Art

Today, it is general to perform an error check in data transmitted between systems or functional devices of a chip. A cyclic redundancy check (CRC) is one of error check techniques mostly used for digital data.

The CRC is a method of determining a check value to verify whether any error(s) is included in data as transmitted upon the data serial transmission through a network or the like. The error checking method by the CRC has high reliability, less overheads for error detection and very good performance in detecting errors including random errors or burst errors.

Accordingly, a CRC value is calculated based on a data value as given before data is transmitted, and the CRC value is transmitted with the data. After the CRC value is recalculated based on the data value received after data is transmission. The two CRC values are compared with each other. If the CRC values are different from each other, an error by noise or the like is checked during the data transmission process.

In addition, scrambling or scrambler has a function of making it impossible to restore or decode data when a scrambler code does not match by randomizing a data pattern or mixing the contents of data by appropriately maintaining the number of bit transition.

Security in digital hardware systems has been maintained usually based on the safety of a hash function or a secret key mainly using symmetric key cipher algorithms. However, the safety dependent on a secret key or hash function value is easily destroyed because a secret key value is exposed by a hardware attack, such as tapping of a system bus or the like.

### SUMMARY OF THE INVENTION

Therefore, it is an object of the present invention to provide a security communication method between devices, whereby all information being likely to be exposed upon the communication is encoded at a high speed and in real time through encoding in a frame structure, a frame data encoding key setting method is changeable during the communication, to prevent any illegal approach from the outside or any copy of a developed product.

The task to be solved by the present invention is not limited to the above described object. The above and other features and advantages of the present invention will become more apparent to those of ordinary skill in the art by describing in detail a preferred embodiment thereof.

In accordance with one embodiment of the present invention, there is provided a security communication method between devices, which is a communication method between a master device and one or more slave devices, comprising the steps of: a) storing two or more CRC polynomials and two or more scramble codes in each of the master device and the one or more slave devices; b) allocating the two or more CRC polynomials and the two or more scramble codes to each of the one more slave devices by the master device; and c) performing each data transmission between the master device and the one or more slave devices, based on the CRC polynomials and scramble code allocated by the step b).

The two or more CRC polynomials are allocated CRC identification numbers, respectively. In the master device and the one or more slave devices, the two or more CRC polynomials and the CRC identification numbers are stored as sets. The two or more scramble codes are allocated code identification number, respectively. In the master device and the one or more slave devices, the two or more scramble codes and the code identification numbers are stored as sets.

The each data transmission between the master device and the one or more slave devices uses a data frame and the data frame includes the CRC identification number and the code identification number.

The each data transmission between the master device and the one or more slave devices uses a data frame and the data frame includes the CRC identification number representing the CRC polynomial or the code identification number representing the scramble code allocated to each of the one or more slave devices.

In accordance with the other embodiment of the present invention, there is provided a security communication method between devices, comprising the steps of: a) preparing two or more CRC polynomials and two or more scramble codes, respectively; b) storing the two or more CRC polynomials and the two or more scramble codes in each of a master device and one or more slave devices; c) allocating the two or more CRC polynomials and the two or more scramble codes to each of the one or more slave devices by the master device; d) performing each data transmission between the master device and the one or more slave devices, based on the CRC polynomials and scramble codes allocated in the step c); e) when the master device changes the CRC polynomials and scramble codes allocated to the one or more slave devices, transmitting data by including a CRC change command and its CRC identification number or a scramble code change command and its code identification number in a data frame to be transmitted by the master device; and f) when the CRC change command or scramble code change command is found in the data frame from the master device, extracting the CRC identification number or code identification number to be changed (which is included in the data frame) by the salve device and processing the data based on the CRC polynomial or scramble code corresponding to the extracted CRC identification number or code identification number.

The two or more CRC polynomials are allocated CRC identification numbers, respectively. In the master device and the one or more slave devices, the two or more CRC polynomials and the CRC identification numbers are stored as sets. The two or more scramble codes are allocated code identification number, respectively. In the master device and the one or more slave devices, the two or more scramble codes and the code identification numbers are stored as sets.

### BRIEF DESCRIPTION OF THE DRAWINGS

The above and other features and advantages of the present invention will become more apparent to those of ordinary skill in the art by describing in detail a preferred embodiment thereof with reference to the attached drawings in which:

FIG. 1 is a block diagram of an example of a system using a security communication method between devices according to an embodiment of the present invention;

FIGS. 2 and 3 are flow charts to explain the operation of the system as shown in FIG. 1;

FIG. 4 is a block diagram of a structure of a frame according to the embodiment of the present invention; and

FIG. 5 is a table of an example of a CRC polynomial set according to the embodiment of the present invention.

### DESCRIPTION OF NUMBERS FOR ELEMENTS IN DRAWINGS

100: master device
200: slave device
110, 210: CRC polynomial set/scramble code set
120, 220: frame/deframe
130, 230: communication interface
140, 240: CRC check_sum generation/CRC check
150, 250: scramble/descramble

### DETAILED DESCRIPTION OF THE PREFERRED EMBODIMENT

The present invention will now be described more fully hereinafter with reference to the accompanying drawings, in which a preferred embodiment of the invention is shown so that those of ordinary skill in the art can easily carry out the present invention.

The present invention may be embodied in different forms and should not be construed as limited to the embodiments set forth herein. Where the function and constitution are irrelevant to the explanation of the present invention, any discussion thereof will be not presented in the detailed description of the present invention. Like numbers refer to like elements throughout the specification.

It will be understood that the terms “comprises”, “comprising”, “includes” and/or “including”, when used herein, specify the presence of steps, elements and/or components, but do not preclude the presence or addition of one or more other steps, elements and/or components unless otherwise defined.

It will be further understood that when a particular allowable error in manufacturing and materials is presented in meaning, the terms “about” and “substantially” are used to mean a numerical value or a proximate value to the numerical value. The terms are also used to prevent an unscrupulous pirate from unfairly using the disclosure mentioning an accurate or absolute numeral value to help a reader understand the present invention.

As used herein, the singular forms “a”, “an” and “the” are intended to include the plural forms as well, unless the context clearly indicates otherwise.

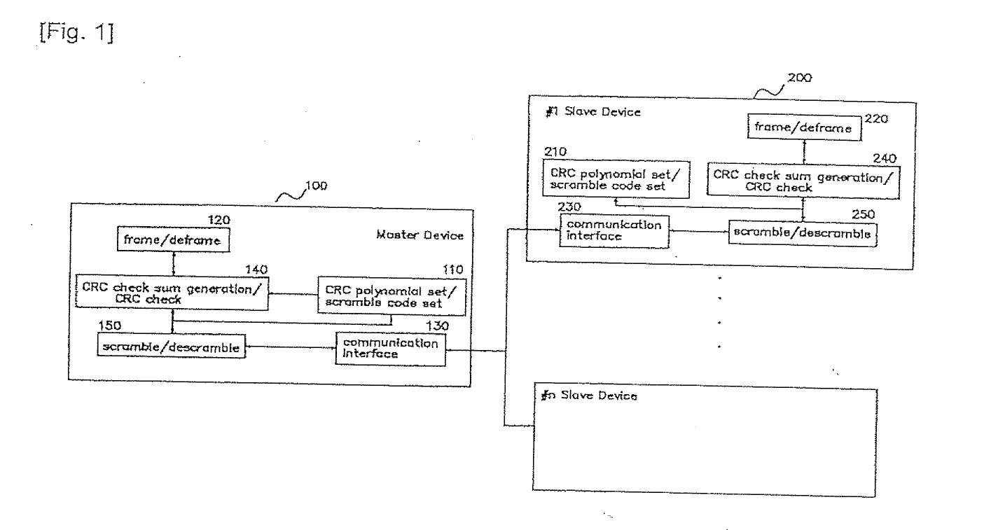

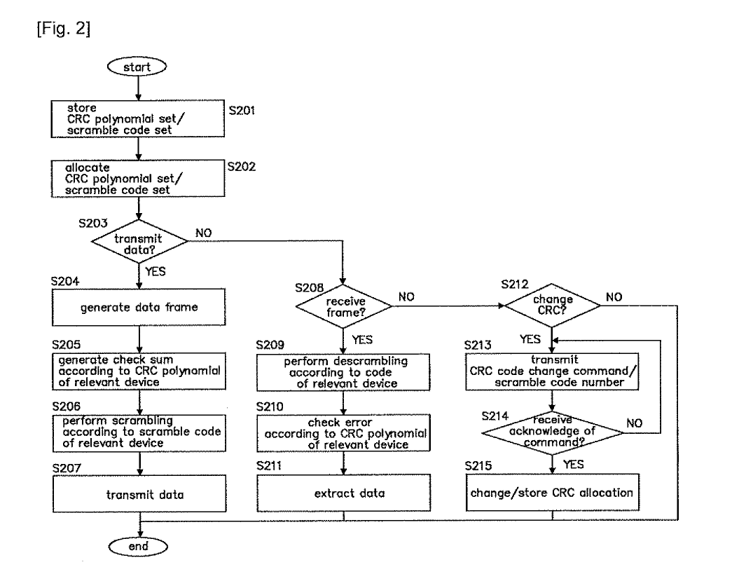

FIG. 1 is a block diagram of an example of a system using a security communication system between devices according to an embodiment of the present invention, and FIGS. 2 and 3 are flow charts to explain the operation of the system as illustrated in FIG. 1.

In FIG. 1, the system using the security communication method between devices according to an embodiment of the present invention comprises a master device 100 and one or more slave devices 200.

The master device 100 and the one or more slave devices 200 exchange data according to the security communication method of the present invention. The master device 100 and the one or more slave devices 200 are connected to communicate each other through their respective communication interfaces 130, 230.

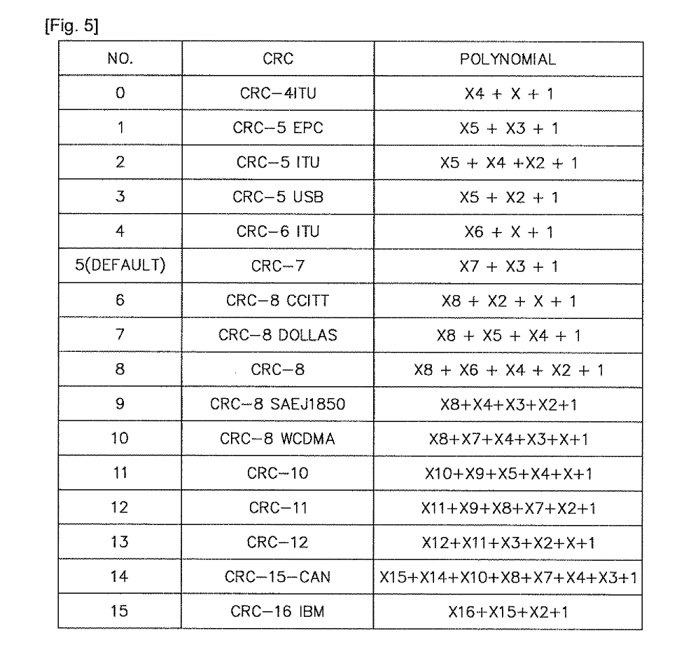

The master device 100 and the one or more slave devices 200 store cyclic redundancy check (CRC) polynomial set 110 including two or more CRC polynomials as prepared according to the present invention. As shown in the table of FIG. 5, the CRC polynomial sets 110 include a number of CRC sets linked to CRC polynomials and CRC numbers representing the CRC polynomials. The master device 100 and the one or more slave devices 200 store scramble code sets 110 including two or more scramble codes as prepared according to the present invention. The scramble code sets 110 comprise scramble codes and code numbers representing the scramble codes.

A framer/deframer 120 of the master device 100 and a framer/deframer 220 of the one or more slave devices 200 generate a data frame from input data, calculate the data frame based on the CRC polynomial and generate a CRC check_sum. Inversely, each of the framer/deframer 120, 220 checks errors in an input data frame from each scrambler/descrambler 150, 250 by using the corresponding CRC polynomial and then outputs data. Each of the scrambler/descrambler 150, 250 scrambles data and CRC check_sum values from the framer/deframer 120, 220 based on the scramble code or descrambles the scrambled data from the communication interfaces 130, 230.

In the present invention, the master device 100 allocates the CRC polynomials and the scramble codes to each of the one or more slave devices 200, checks an error by using the CRC polynomial corresponding to each slave device 200 and data transmission and encodes data. Therefore, when data is received in any slave devices 200 or devices other than the device to which the data is intended to be transmitted, it is impossible to decode the received data and to check the error unless the CRC polynomial calculated in the master device 100 is known or the scramble code is known.

The master device 100 is capable to change frequently, selectively and randomly the CRC polynomial and/or the scramble code allocated to each of the slave devices 200. When the master device 100 is intended to change the CRC polynomial and/or the scramble code, the master device 100 transmits a CRC change command and/or a scramble code change command and a new CRC number and/or a new scramble code number when transmitting data to the relevant slave device 200. The slave device 200 receiving them changes the CRC polynomial and/or the scramble code, based on the CRC change command and/or the scramble code change command. Accordingly, even though any other outside device(s) catches the data, it is unable to decode the data and check the error because the CRC polynomial and/or the scramble code is randomly changed.

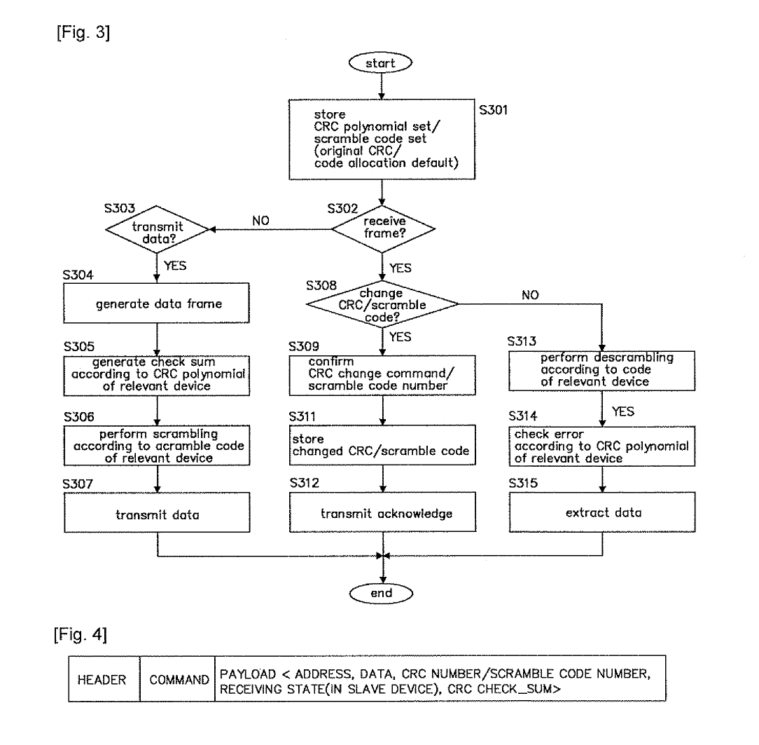

As illustrated in FIG. 4, the data frame according to the present invention comprises a header, a command to change a CRC and/or scramble code, and a payload. The payload includes a data address, data, a CRC number and/or a scramble code number, a receiving status (in a slave device) and a CRC check-sum. Thus, when the master device 100 changes the CRC polynomial and/or the scramble code, it newly allocates CRC polynomials and/or scramble codes to the slave devices 200 and transmits a CRC change command and/or a scramble code change command and a new CRC number and/or scramble code number thereof, to set a new CRC polynomial and/or scramble code with each of the slave devices 200.

The operation of the system having the above-described constitution will be described in more detail with reference to FIGS. 2 and 3.

FIG. 2 is a flow chart illustrating the operation of the master slave 100 according to the present invention and FIG. 3 is a flow chart illustrating the operation of the slave device 200 according to the present invention. Herein, one slave device 200 is explained as an example for making it easier to understand the invention. However, it will be noted that one or more slave devices 200 may be included.

In FIG. 2, the master device 100 stores CRC polynomial sets including two or more CRC polynomials and scramble code sets including to be used for an error check when communicating with the slave device 200. The same CRC polynomial set and scramble code set are stored in the slave device 200. In step S201 and step S202, the CRC polynomials and scramble codes are allocated to each of the slave devices 200.

In step S203 through step S207, upon data transmission, the master device 100 generates a data check sum by using the CRC polynomial corresponding to the slave device 200 to which data is to be transmitted, encodes the generated check sum and data by using the corresponding scramble code, and transmits the data.

In step S208 through step S211, when the master device 100 receives the data from the slave device 200, the master device 100 descrambles the received data by using the scramble code and then checks an error in the descrambled data by using the CRC polynomial.

To change the CRC polynomial and/or the scramble code, the master device 100 allocates a new CRC polynomial and/or a new scramble code to the slave device 20, stores the new CRC polynomial and/or the new scramble code, and then transmits a CRC change command and/or a scramble code change command, and a CRC number to be changed and/or a code number to be changed to the slave device 200. Then, the slave device 200 changes the CRC polynomial and/or the scramble code in accordance with the command(s), the CRC number and/or the scramble code number and transmits a confirmation message to the master device 100. Subsequently, when the master device 100 receives the confirmation message of the CRC polynomial change and/or scramble code change from the slave device, the master device 100 performs the data communication with the slave device 200 by using the changed CRC polynomial and/or scramble code after the CRC polynomial change and/or the scramble code change is completed.

In step S301, the slave device 200 stores the same CRC polynomial set and scramble code set as those of the master device as described above.

In step S302 through S307, unless otherwise commands from the master device 100 are received, the master device 100 performs the communication by using the default CRC polynomial and scramble code.

In step S308 through S315, when the CRC change command and/or the scramble code change command are/is included in a data frame from the master device 100, the slave device 100 changes the CRC polynomial and/or the scramble code based on the CRC number and/or the scramble code number which are transmitted together with the command(s) and uses the changed CRC polynomial in checking a data error and generating a check sum of the data to be transmitted, and the slave device 100 uses the scramble code in encoding and decoding the data.

According to the present invention, since the CRC polynomials used for the data transmission between devices are individually used, the CRC not only performs an error correction but also better tightens the data security.

As described above, when the communication between the (parent) processor and the child device(s) is based on the frame, it is possible to encode all information being likely to be exposed upon the communication, at a high speed and in real time, through encoding in the structure of the frame, and it is also possible to change the frame data encoding key setting method while the communication is performed, to prevent any illegal approach from the outside or any copy of a developed product. Therefore, protocol information, security-related information, secret key values, and the like are not exposed during the communication, thereby maximizing high-speed process and security.

The invention has been described using a preferred exemplary embodiment. However, it is to be understood that the scope of the invention is not limited to the disclosed embodiment. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A security communication method between devices, which is a communication method between a master device and one or more slave devices, comprising the steps of:
a) storing two or more CRC (cyclic redundancy check) polynomials and two or more scramble codes in each of the master device and the one or more slave devices;
b) allocating the two or more CRC polynomials and the two or more scramble codes to each of the one or more slave devices by the master device; and
c) performing each data transmission between the master device and the one or more slave devices, based on the CRC polynomial and scramble code as allocated in the step b).

2. The security communication method according to claim 1, wherein each of the two or more CRC polynomials is allocated a CRC identification number, and the master device and the one or more slave devices store the two or more CRC polynomials and the CRC identification numbers as sets,
wherein each of the two or more scramble codes is allocated a code identification number, and the master device and the one or more slave devices store the two or more scramble codes and the code identification numbers as sets.

3. The security communication method according to claim 1, wherein each data transmission between the master device and the one or more slave devices uses a data frame, and the data frame includes the CRC identification number or the code identification number.

4. The security communication method according to claim 2, wherein each data transmission between the master device and the one or more slave devices uses a data frame, and the data frame includes the CRC identification number or the code identification number.

5. The security communication method according to claim 3, wherein each data transmission between the master device and the one or more slave devices uses a data frame, and the data frame includes a CRC identification number representing the CRC polynomial allocated to each of the one or more slave devices, or a code identification number representing the scramble code allocated to each of the one or more slave devices.

6. The security communication method according to claim 4, wherein each data transmission between the master device and the one or more slave devices uses a data frame, and the data frame includes a CRC identification number representing the CRC polynomial allocated to each of the one or more slave devices, or a code identification number representing the scramble code allocated to each of the one or more slave devices.

7. A security communication method between devices, comprising the steps of:
a) preparing two or more CRC polynomials and two or more scramble codes;
b) storing the two or more CRC polynomials and the two or more scramble codes in each of a master device and one or more slave devices;
c) allocating the two or more CRC polynomials and the two or more scramble codes to each of the one or more slave devices by the master device;
d) performing each data transmission between the master device and the one or more slave devices, based on the CRC polynomial and scramble code as allocated in the step c);
e) when the master device changes the CRC polynomials or scramble codes allocated to the one or more slave devices, including a CRC change command and its CRC identification number or a scramble code change command and its code identification number in a data frame to be transmitted, and then transmitting the data frame by the master device; and
f) when the slave device finds the CRC change command or scramble code change command in the data frame transmitted from the master device, extracting the CRC identification number or code identification number to be changed (as included in the data frame), and processing the data based on the CRC polynomial or scramble code corresponding to the extracted CRC identification number or code identification number by the slave device.

8. The security communication method according to claim 7, wherein each of the two or more CRC polynomials is allocated a CRC identification number, and the master device and the one or more slave devices store the two or more CRC polynomials and the CRC identification numbers as sets,
wherein each of the two or more scramble codes is allocated a code identification number, and the master device and the one or more slave devices store the two or more scramble codes and the code identification numbers as sets.
